(19) United States
(12) Patent Application Publication
(10) Pub. No.: US 2015/0146395 A1
(43) Pub. Date: May 28, 2015

(54) ELECTRICALLY CONDUCTIVE MATERIAL

(71) Applicant: LOTES Co., Ltd, Keelung (TW)

(72) Inventors: Ted Ju, Keelung (TW); Kai Tze Huang, Keelung (TW); Chien Chih Ho, Keelung (TW); Tien Chih Yu, Keelung (TW); Chin Chi Lin, Keelung (TW)

(21) Appl. No.: 14/554,598

(22) Filed: Nov. 26, 2014

(30) Foreign Application Priority Data
Nov. 27, 2013 (CN) 201320750530.9

(51) Int. Cl. H01B 1/02; H05K 1/14; H05K 1/09; H05K 1/18

(52) U.S. Cl. CPC H01B 1/02; H05K 1/181; H05K 1/141; H05K 1/09; H01B 1/026; H05K 2201/042; H05K 2201/0364
USPC 361/760; 174/126.1; 361/679.01; 361/748; 361/803; 428/457; 428/328; 428/446

(57) ABSTRACT

An electrically conductive material includes a liquid gallium alloy mixed with multiple solid particles, so as to form an electrically conductive material in which solid and liquid coexist. The electrically conductive material is disposed between and electrically connecting a first conductor and a second conductor. The first conductor is disposed on a first electronic element, and the second conductor is disposed on a second electronic element.

### CROSS-REFERENCE TO RELATED APPLICATION

This non-provisional application claims priority under 35 U.S.C. §119(a) on Patent Application No. 201320750530.9 filed in P.R. China on Nov. 27, 2013, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates to an electrically conductive material, and more particularly to an electrically conductive material for connecting electronic elements.

### BACKGROUND OF THE INVENTION

Currently electrical connection between two electronic elements is usually achieved by using metal electrically conductive terminals in the industry. To meet requirements of light weight and small thickness, electronic products become thinner in height and smaller in volume, and in this case, the arrangement of electrically conductive terminals on an electronic element is required to be denser. To meet such dense arrangement, electrically conductive terminals need to be reduced in height, length, and width, and such an approach leads to defective situations such as insufficient elasticity, easy fracture, and difficult processing of terminals, which all affect signal transmission of electronic elements.

Therefore, it is necessary to design a new electrically conductive material for connecting electronic elements to overcome the foregoing problems.

### SUMMARY OF THE INVENTION

In one aspect, the present invention is directed to an electrically conductive material that can reduce connecting thickness of electronic elements, is easy to process, and has desirable electrical conductivity performance.

In one embodiment, an electrically conductive material includes a liquid gallium alloy mixed with multiple solid particles, so as to form an electrically conductive material in which solid and liquid coexist. The electrically conductive material is disposed between a first conductor and a second conductor for electrical connection.

In one embodiment, the solid particle can reduce surface tension of the liquid gallium alloy.

In one embodiment, the solid particle is a metal body.

In one embodiment, the solid particle is a nonmetal body.

In one embodiment, the nonmetal body is made of a polymer material.

In one embodiment, the polymer material is silica gel, resin or rubber.

In one embodiment, an antioxidation layer is disposed outside the metal body.

In one embodiment, the antioxidation layer can react with the liquid gallium alloy.

In one embodiment, the antioxidation layer is made of silver, gold or palladium.

In one embodiment, the metal body is one or a mixture of iron, copper, nickel or silver.

In one embodiment, the metal body is iron.

In one embodiment, the particle size of the solid particle is greater than 1 μm.

In one embodiment, the particle size of the solid particle is between 1 μm and 100 μm.

In one embodiment, a volume ratio of the solid particles in the electrically conductive material is greater than 50%.

In one embodiment, a mass ratio of the solid particles in the electrically conductive material is greater than 50%.

In one embodiment, the gallium alloy has a melting point lower than 40° C.

In one embodiment, the first conductor is a tin ball, and the tin ball is at least partially inserted in the electrically conductive material.

In one embodiment, the first conductor is a pin or an elastic sheet, and the pin or the elastic sheet at least partially contacts the electrically conductive material.

In one embodiment, the first conductor does not react with the electrically conductive material.

In one embodiment, the first conductor is a copper ball, and the copper ball is at least partially inserted in the electrically conductive material.

In one embodiment, the first conductor is disposed on a first electronic element.

In one embodiment, the second conductor is disposed on a second electronic element.

In one embodiment, multiple first conductors are disposed on the first electronic element, the second conductors of the same number corresponding to the first conductors are disposed on the second electronic element, and the first conductors and the second conductors are electrically connected through the electrically conductive material.

In one embodiment, at least one isolating block is disposed between the first electronic element and the second electronic element, and an upper surface and a lower surface of the isolating block abut the first electronic element and the second electronic element respectively.

In one embodiment, at least one barrier is disposed between the adjacent electrically conductive materials.

In one embodiment, a positioning apparatus is further disposed. The positioning apparatus prevents relative movement of the first electronic element and the second electronic element in a plane direction of the second electronic element.

In one embodiment, a third conductor is located at an opposite side, relative to the second conductor, of the second electronic element. The third conductor has a guiding portion for connecting the second conductor and the third conductor.

In one embodiment, a third electronic element is located at a side of the second electronic element, and is electrically connected to the third conductor.

As compared with the related art, the electrically conductive material of the present invention can directly electrically connect the first electronic element and the second electronic element, thereby greatly reducing connecting thickness of the first electronic element and the second electronic element without affecting signal transmission between the first electronic element and the second electronic element. The isolating block and the positioning apparatus can desirably prevent relative movement of the first electronic element and the second electronic element in a connecting plane and a vertical plane, and provide guidance and positioning for lamination of the first electronic element and the second electronic element. The barrier can effectively isolate the adjacent electrically conductive materials and reduce the occurrence of short circuit phenomena, so as to achieve accurate signal conduction between electronic elements. Multiple solid particles are added to the liquid gallium alloy, so that surface tension of the liquid gallium alloy can be reduced, making it easy for the electrically conductive material to pass through mesh holes of a mesh plate to be attached to a surface of the first conductor for electrical connection, and meanwhile the usage of the liquid gallium alloy can be reduced, thereby reducing a production cost.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention.

Wherever possible, the same reference numbers are used throughout the drawings to refer to the same or like elements of an embodiment.

FIG. 1 is a schematic sectional view according to a first embodiment of the present invention.

FIG. 2 is schematic a sectional view according to a second embodiment of the present invention.

FIG. 3 is a schematic sectional view according to a third embodiment of the present invention.

FIG. 4 is a schematic sectional view according to a fourth embodiment of the present invention.

FIG. 5 is a schematic sectional view according to a fifth embodiment of the present invention.

FIG. 6 is a schematic sectional view according to a sixth embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

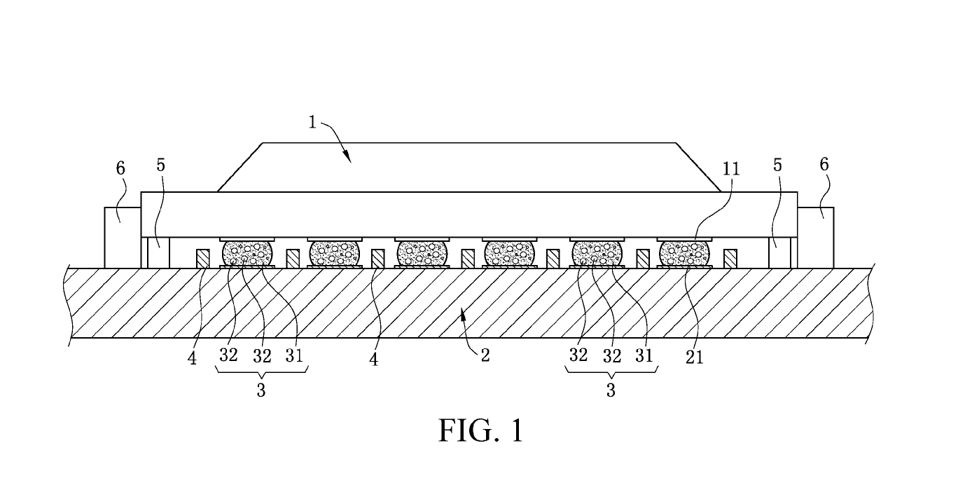

The description will be made as to the embodiments of the present invention in conjunction with the accompanying drawings in FIGS. 1-6. In accordance with the purposes of this invention, as embodied and broadly described herein, this invention, in one aspect, relates to an electrical conductive material.

As shown in FIG. 1, an electrically conductive material 3 according to one embodiment of the present invention is used for electrically connecting a first electronic element 1 and a second electronic element 2. In one embodiment, the first electronic element 1 is a chip module, the second electronic element 2 is a circuit board. Multiple first conductors 11 are disposed on the first electronic element 1, and multiple second conductors 21 are disposed on the second electronic element 2. The electrically conductive material 3 is disposed between the first electronic element 1 and the second electronic element 2, and contacts the first conductor 11 and the second conductor 21 at the same time.

Referring to FIG. 1, in this first embodiment of the present invention, both the first conductors 11 and the second conductor 21 are metal sheets. The multiple first conductors 11 are provided in a downward protruding manner on a lower surface of the first electronic element 1, and the first conductors 11 are arranged in an array. The multiple second conductors 21 that correspond to the first conductors 11 one by one are provided in an upward protruding manner on an upper surface of the second electronic element 2. The electrically conductive material 3 is disposed between the first conductor 11 and the corresponding second conductor 21, and contacts the first conductor 11 and the corresponding second conductor 21 to electrically connect the first electronic element 1 and the second electronic element 2.

The electrically conductive material 3 is located between the first electronic element 1 and the second electronic element 2, and contacts the first conductor 11 and the second conductor 21 at the same time, so as to achieve electrical conduction between the first electronic element 1 and the second electronic element 2. The electrically conductive material 3 includes a liquid gallium alloy 31 and solid particles 32 and is in a state in which solid and liquid coexist. In other words, the liquid gallium alloy 31 is substantially in a liquid state in the electrically conductive material 3, and the solid particles 32 are substantially in a solid state in the electrically conductive material 3.

The liquid gallium alloy 31 has a melting point lower than 40° C., and at atmospheric temperature, the liquid gallium alloy 31 connects, in a liquid form, the first conductor 11 and the second conductor 21 to achieve electrical connection. The solid particles 32 are added to the liquid gallium alloy 31 to effectively reduce surface tension of the liquid gallium alloy 31, so that the liquid gallium alloy 31 can be easily laid out and attached to the surfaces of the first conductor 11 and the second conductor 21, and the industrial production becomes simpler and more convenient. A volume or mass ratio of the solid particles 32 in the electrically conductive material 3 is greater than 50%, and the particle size of the solid particle 32 is between 1 μm and 100 μm. In this way, without affecting electrical connection between the first electronic element 1 and the second electronic element 2, the usage of the liquid gallium alloy 31 is reduced, thereby reducing the cost. Moreover, the electrically conductive material 3 is a body in which solid and liquid coexist, so that the first conductor 11 and the second conductor 21 have a large contact area and small impedance, and during current transmission, energy is not consumed due to impedance, thereby ensuring the stability of current transmission and a desirable effect of electrical connection.

The foregoing solid particle 32 may be a metal body, for example, one or a mixture of several of iron, copper, nickel or silver. An antioxidation layer (not shown) is disposed outside the metal body, for example, silver, gold or palladium layer, so as to effectively prevent a reaction between the metal body and the liquid gallium alloy 31, thereby achieving reduction of surface tension of the liquid gallium alloy 31. Moreover, the solid particles 32 may also be a nonmetal body, for example, a polymer material such as silica gel, resin or rubber, so as to reduce the usage of the liquid gallium alloy 31, thereby reducing the cost.

At least one barrier 4 is provided in an upward protruding manner on the upper surface of the second electronic element 2. The barrier 4 is located between the two adjacent electrically conductive materials 3, so as to prevent short circuit between two adjacent electrically conductive materials 3. In this embodiment, an upper surface of the barrier 4 does not contact the first electronic element 1. In other embodiments, the upper surface of the barrier 4 may contact the first electronic element 1. The barrier 4 may be integrated with the second electronic element 2, or may also be disposed separately from the second electronic element 2. At least one isolating block 5 is disposed between the first electronic element 1 and the second electronic element 2. An upper surface and a lower surface of the isolating block 5 abut the first electronic element 1 and the second electronic element 2, respectively, so as to keep a suitable interval between the first electronic element 1 and the second electronic element 2 to receive the electrically conductive material 3. A positioning apparatus 6 is further provided on the second electronic element 2. In this embodiment, the positioning apparatus 6 are two protruding portions (not shown) provided in an upward protruding manner on the upper surface of the second electronic element 2, and located at two sides of the first electronic element 1, respectively. The positioning apparatus 6 abut two opposite sides of the first electronic element 1 in a horizontal direction, so as to prevent relative movement of the first electronic element 1 and the second electronic element 2 in a horizontal direction.

The positioning apparatus 6 is used for providing guidance and positioning for lamination of the first electronic element 1 and the second electronic element 2, so as to achieve accurate positioning of the first electronic element 1 and the second electronic element 2.

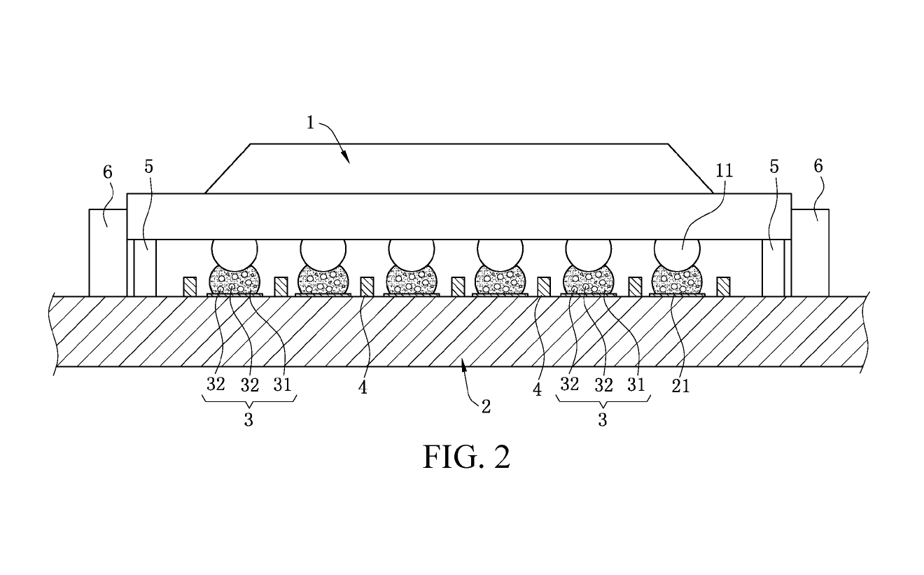

As shown in FIG. 2, a second embodiment is basically the same as the first embodiment in structure, and a difference lies in that the first conductor 11 is a copper ball (in other embodiments, the first conductor may also be a tin ball). The first conductor 11 does not react with the electrically conductive material 3 easily, and is at least partially inserted in the electrically conductive material 3, so as to increase a contact area between the first conductor 11 and the electrically conductive material 3, thereby achieving better contact between the first conductor 11 and the electrically conductive material 3.

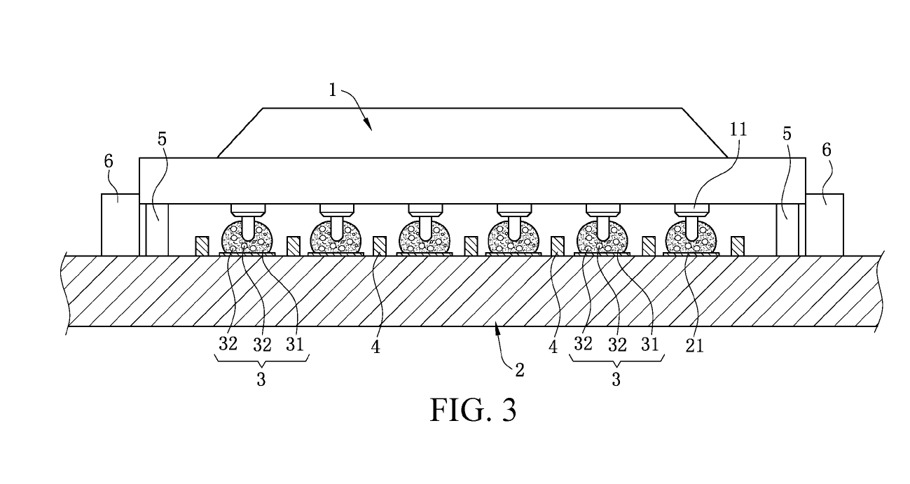

As shown in FIG. 3, a third embodiment is basically the same as the first embodiment in structure, and a difference is that the first conductor 11 is a pin, and is at least partially inserted in the electrically conductive material 3, so as to achieve full contact between the first conductor 11 and the electrically conductive material 3.

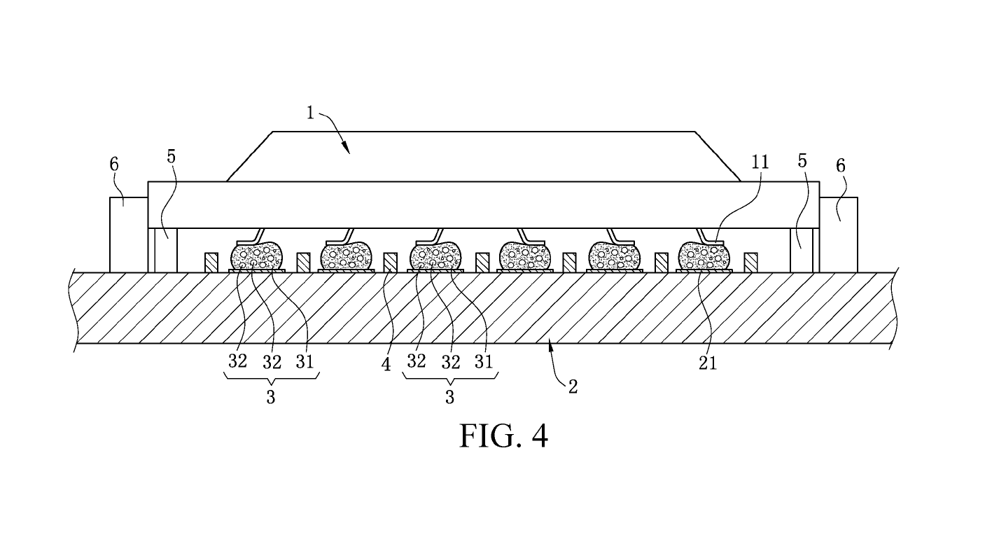

As shown in FIG. 4, a fourth embodiment is basically the same as the first embodiment in structure, and a difference is that the first conductor 11 is an elastic sheet, and at least partially contacts the electrically conductive material 3, so as to achieve desirable contact between the first conductor 11 and the electrically conductive material 3.

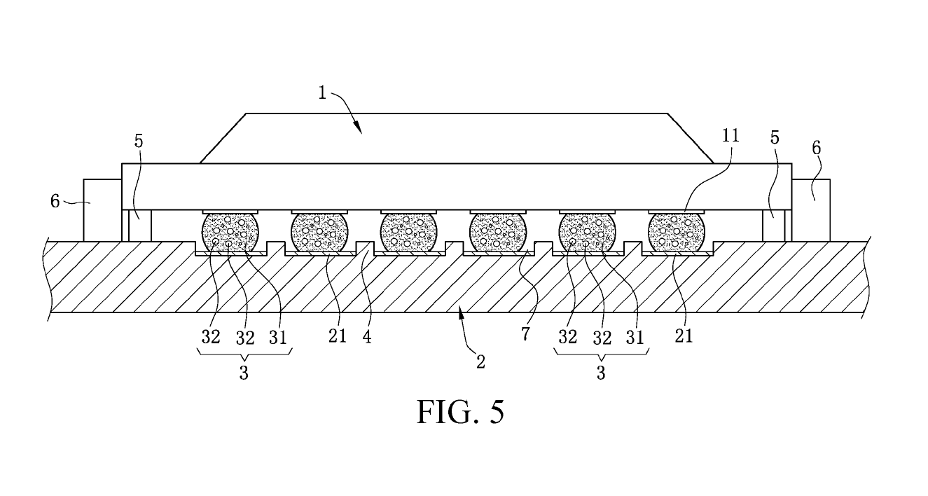

As shown in FIG. 5, a difference between a fifth embodiment and the first embodiment lies in that multiple grooves 7 are disposed on the second electronic element 2. The grooves 7 correspond to the first conductors 11 one by one, and the second conductors 21 are respectively disposed inside the grooves 7. In this embodiment, both the first conductor 11 and the second conductor 21 are metal sheet. The electrically conductive material 3 is disposed between the first conductor 11 and the second conductor 21, and is at least partially located inside the groove 7, so that the grooves 7 can prevent short circuit between the adjacent electrically conductive materials 3. The barrier 4 is disposed between the two adjacent grooves 7, and a top surface of the barrier 4 is flush with the upper surface of the second electronic element 2.

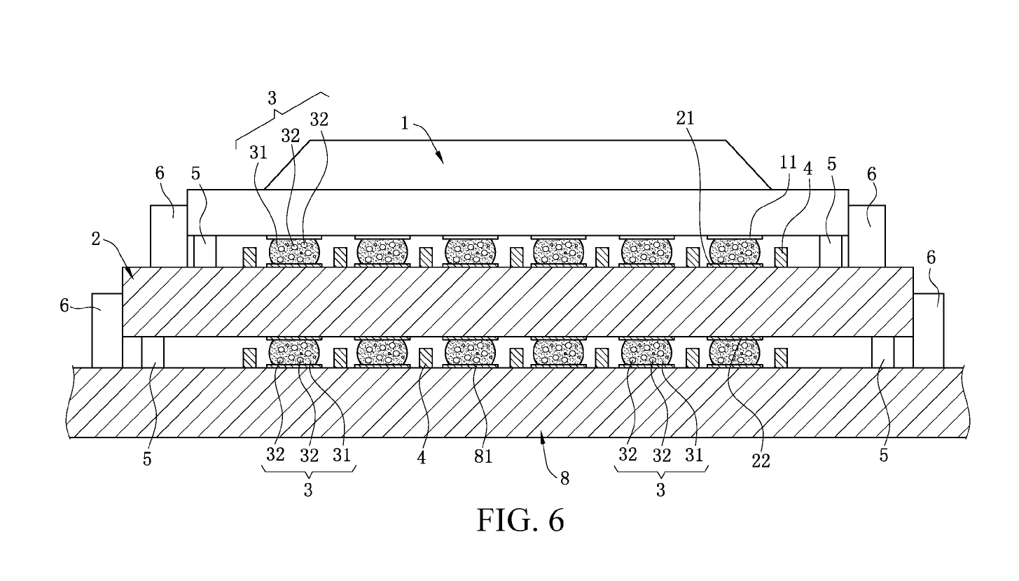

As shown in FIG. 6, a sixth embodiment is basically the same as the first embodiment in structure, and a difference lies in that a third electronic element 8 is added below the second electronic element 2. In this embodiment, the third electronic element 8 is a circuit board. Multiple third conductors 22 are disposed on a lower surface of the second electronic element 2 and correspond to the second conductors 21 one by one. Conduction between the second conductor 21 and the third conductor 22 may be achieved through a circuit inside the second electronic element 2. As shown in FIG. 6, same as the second electronic element 2 in the first embodiment, multiple fourth conductors 81 are disposed on an upper surface of the third electronic element 8. In one embodiment, the fourth conductor 81 is a metal sheet, and the fourth conductors 81 correspond to the third conductors 22 one by one. The fourth conductor 81 and the corresponding third conductor 22 are electrically connected through the electrically conductive material 3. The barrier 4 that is located between the adjacent electrically conductive materials 3 is disposed on the third electronic element 8. Moreover, the isolating block 5 and the positioning apparatus 6 are disposed on the third electronic element 8. The isolating block 5 and the positioning apparatus 6 are used for providing guidance and positioning for lamination of the second electronic element 2 and the third electronic element 8, so as to achieve accurate positioning of the second electronic element 2 on the third electronic element 8.

In the embodiments of the present invention, the electrically conductive material 3 is first applied to the upper surface of the second electronic element 2, and the electrically conductive material 3 is attached to the second conductor 21 through holes of a mesh plate. Moreover, the barrier 4 disposed on the second electronic element 2 can isolate the adjacent electrically conductive materials 3, so as to prevent contact between the adjacent electrically conductive materials 3 that causes short circuit because the electrically conductive material 3 has high flowability. Then the first electronic element 1 is laminated above the second electronic element 2 under the guidance and positioning of the isolating block 5 and the positioning apparatus 6, so as to achieve electrical connection between the first conductor 11 and the second conductor 21 through the electrically conductive material 3. In other embodiments, the electrically conductive material 3 may also be attached on the first conductor 11 and then contact the second electronic element 2, so as to achieve electrical connection.

The electrically conductive material according to certain embodiment of the present invention, among other things, has the following beneficial advantages.

(1) In the present invention, the first electronic element and the second electronic element are directly electrically connected through the electrically conductive material, and defective situations such as insufficient elasticity, easy fracture, and difficult processing of electrically conductive terminals do not exist, and at the same time the thickness of a connector can be greatly reduced and signal transmission between the first electronic element and the second electronic element can be achieved.

(2) The electrically conductive material is a body in which solid and liquid coexist, so that the first conductor and the second conductor have a large contact area and small impedance, and during current transmission, energy is not consumed due to impedance, thereby ensuring the stability of current transmission and a desirable effect of electrical connection.

(3) The solid particles are added to the liquid gallium alloy to reduce surface tension of the liquid gallium alloy, so that the liquid metal can be easily laid out and attached to the surfaces of the first conductor and the second conductor, and the usage of the liquid gallium alloy is reduced, thereby reducing the production cost.

(4) A metal layer is disposed outside the metal body, so that the metal body and the liquid gallium alloy can be isolated, thereby effectively preventing an alloy reaction between the metal body and the liquid gallium alloy.

(5) The barrier effectively prevents the occurrence of short circuit caused by contact between two adjacent electrically conductive materials because the electrically conductive material is a body in which solid and liquid coexist and has high flowability.

(6) The isolating block and the positioning apparatus are used for providing guidance and positioning for lamination of the first electronic element and the second electronic element, so as to achieve accurate positioning between the first electronic element and the second electronic element.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electrically conductive material, comprising:
a liquid gallium alloy mixed with a plurality of solid particles, such that solid and liquid coexist in the electrically conductive material,
wherein the electrically conductive material is disposed between and electrically connecting a first conductor and a second conductor.

2. The electrically conductive material of claim 1, wherein the solid particle is capable of reducing surface tension of the liquid gallium alloy.

3. The electrically conductive material of claim 1, wherein the solid particle is a metal body.

4. The electrically conductive material of claim 3, wherein an antioxidation layer is disposed outside the metal body.

5. The electrically conductive material of claim 4, wherein the antioxidation layer is capable of reacting with the liquid gallium alloy.

6. The electrically conductive material of claim 4, wherein the antioxidation layer is made of silver, gold or palladium.

7. The electrically conductive material of claim 3, wherein the metal body is made of at least one of iron, copper, nickel or silver.

8. The electrically conductive material of claim 3, wherein the metal body is made of iron.

9. The electrically conductive material of claim 1, wherein the solid particle is a nonmetal body.

10. The electrically conductive material of claim 9, wherein the nonmetal body is made of a polymer material.

11. The electrically conductive material of claim 10, wherein the polymer material is silica gel, resin or rubber.

12. The electrically conductive material of claim 1, wherein the particle size of the solid particle is greater than 1 μm.

13. The electrically conductive material of claim 1, wherein the particle size of the solid particle is between 1 μm and 100 μm.

14. The electrically conductive material of claim 1, wherein a volume ratio of the solid particles in the electrically conductive material is greater than 50%.

15. The electrically conductive material of claim 1, wherein a mass ratio of the solid particles in the electrically conductive material is greater than 50%.

16. The electrically conductive material of claim 1, wherein the gallium alloy has a melting point lower than 40° C.

17. The electrically conductive material of claim 1, wherein the first conductor is a tin ball, and the tin ball is at least partially inserted in the electrically conductive material.

18. The electrically conductive material of claim 1, wherein the first conductor is a pin or an elastic sheet, and the pin or the elastic sheet at least partially contacts the electrically conductive material.

19. The electrically conductive material of claim 1, wherein the first conductor does not react with the electrically conductive material.

20. The electrically conductive material of claim 1, wherein the first conductor is a copper ball, and the copper ball is at least partially inserted in the electrically conductive material.

21. The electrically conductive material of claim 1, wherein the first conductor is disposed on a first electronic element.

22. The electrically conductive material of claim 21, wherein the second conductor is disposed on a second electronic element.

23. The electrically conductive material of claim 22, wherein a plurality of the first conductors are disposed on the first electronic element, a plurality of the second conductors respectively corresponding to the first conductors are disposed on the second electronic element, and the first conductors and the second conductors are electrically connected through the electrically conductive material.

24. The electrically conductive material of claim 23, wherein at least one isolating block is disposed between the first electronic element and the second electronic element, and an upper surface and a lower surface of the isolating block abut the first electronic element and the second electronic element respectively.

25. The electrically conductive material of claim 23, wherein at least one barrier is disposed between the adjacent electrically conductive materials.

26. The electrically conductive material of claim 23, wherein a positioning apparatus is further disposed for preventing relative movement of the first electronic element and the second electronic element in a plane direction of the second electronic element.

27. The electrically conductive material of claim 23, wherein a third conductor is located at an opposite side, relative to the second conductor, of the second electronic element, and a guiding portion is disposed for connecting the second conductor and the third conductor.

28. The electrically conductive material of claim 27, wherein a third electronic element is located at a side of the second electronic element, and electrically connects to the third conductor.
